(19) United States
(12) Patent Application Publication
(10) Pub. No.: US 2025/0379130 A1
(43) Pub. Date: Dec. 11, 2025

(54) PACKAGE SUBSTRATE AND FABRICATING METHOD THEREOF

(71) Applicant: SILICONWARE PRECISION INDUSTRIES CO., LTD., Taichung City (TW)

(72) Inventors: Pao-Hung TSENG, Taichung City (TW); Yu-Cheng PAI, Taichung City (TW); Yuan-Ping YEH, Taichung City (TW)

(73) Assignee: SILICONWARE PRECISION INDUSTRIES CO., LTD., Taichung City (TW)

(21) Appl. No.: 18/806,055

(22) Filed: Aug. 15, 2024

(30) Foreign Application Priority Data
Jun. 5, 2024 (TW) 113120889

(51) Int. Cl. H01L 23/498; H01L 21/48; H01L 21/683; H01L 23/00

(52) U.S. Cl. CPC H01L 23/49822; H01L 21/4857; H01L 21/486; H01L 21/6835; H01L 23/49838; H01L 24/16; H01L 2221/68345; H01L 2221/68359; H01L 2224/16227; H01L 2224/16237; H01L 2924/384

(57) ABSTRACT

Provided is a package substrate which is manufactured by forming a heterogeneous layer on a board body for forming a circuit structure on the heterogeneous layer, and then removing the board body. Hence, a circuit layer of the circuit structure will not be etched when the heterogeneous layer is subsequently removed. Therefore, solder balls can be effectively bonded to the circuit layer in subsequent processes to avoid a non-wetting issue.

### BACKGROUND

### 1. Technical Field

The present disclosure relates to a semiconductor packaging process, and more particularly, to a package substrate and a manufacturing method thereof that can enhance reliability.

### 2. Description of Related Art

With the vigorous development of the electronics industry, electronic products tend to be a thin, light, and small type, and the development of functions towards high performance, high functionality and high speed. Therefore, in order to meet the high integration and miniaturization requirements of semiconductor devices, package substrates with high-density and fine-pitch circuits are often used in the packaging process.

FIG. 1A to FIG. 1F are schematic cross-sectional views of a manufacturing method of conventional package substrate 1.

As shown in FIG. 1A, a carrier 9 includes release layers 91 respectively formed on two surfaces of a board body 90, and a copper foil 92 is formed on the release layer 91.

As shown in FIG. 1B, a patterning process is performed on the copper foil 92 to form a first circuit layer 11.

As shown in FIG. 1C, a dielectric layer 12 is formed on the first circuit layer 11, and a plurality of blind holes 120 are formed in the dielectric layer 12.

As shown in FIG. 1D, a copper material is electroplated on the dielectric layer 12 and in the blind holes 120 to form a second circuit layer 13 on the dielectric layer 12. A plurality of conductive blind holes 14 electrically connected to the first circuit layer 11 and the second circuit layer 13 are formed in the blind hole 120 to form a coreless circuit structure 1a.

As shown in FIG. 1E, the board body 90 and the circuit structure 1a are separated by the release layer 91, and the copper foil 92 is remained on the dielectric layer 12 and the first circuit layer 11.

As shown in FIG. 1F, the copper foil 92 is removed by etching, and part of material of the first circuit layer 11 is etched to avoid short circuits caused by connection between adjacent circuits, and thus a plurality of grooves 15 are formed on the dielectric layer 12.

As shown in FIG. 1G, a solder mask layer 10 having a plurality of openings 100 is formed on opposite sides of the dielectric layer 12, thereby part of the surface of the first circuit layer 11 and the second circuit layer 13 are exposed from the openings for an electronic device 3 being connected to the first circuit layer 11 through a plurality of solder balls 16.

However, in the conventional package substrate 1, when the copper foil 92 is removed by etching, the first circuit layer 11 will also be micro-etched, and resulting in inconsistent depths D of the grooves 15. Therefore, it would be difficult for the first circuit layer 11 to effectively bond to all the solder balls 16, leading to poor reliability of the package substrate 1. For example, the depth of part of the grooves 15 is too deep for the solder ball 16 to bond to the first circuit layer 11, causing problems of solder empty or non-wetting.

Furthermore, since the first circuit layer 11 is micro-etched when the copper foil 92 is removed by etching, part of the first circuit layer 11 is thus lateral etched, the first circuit layer 11 is damaged or even break, causing a poor signal transmission between the first circuit layer 11 and the solder ball 16.

Therefore, there is a need for addressing the aforementioned shortcomings in the prior art.

### SUMMARY

In view of the aforementioned shortcomings of the prior art, the present disclosure provides a package substrate including a dielectric layer having a first surface and a second surface opposite to the first surface; a first circuit layer embedded in the first surface of the dielectric layer, wherein the first circuit layer is flush with the first surface of the dielectric layer; a heterogeneous layer formed on the first surface of the dielectric layer; a second circuit layer formed on the second surface of the dielectric layer; and a plurality of conductive blind holes formed in the dielectric layer and electrically connected to the first circuit layer and the second circuit layer.

The present disclosure also provides a method of manufacturing a package substrate, including: providing a board body having a heterogeneous layer thereon; forming a first circuit layer on the heterogeneous layer; forming a dielectric layer on the heterogeneous layer and the first circuit layer, wherein the dielectric layer is defined with a first surface and a second surface opposite to the first surface, and the first surface of the dielectric layer is bonded to the heterogeneous layer; forming a second circuit layer on the second surface of the dielectric layer, and forming a plurality of conductive blind holes in the dielectric layer for electrically connecting the first circuit layer and the second circuit layer in the dielectric layer; and removing the board body.

In the aforementioned method, a release layer is first formed on the board body, and then the heterogeneous layer is formed on the release layer.

In the aforementioned method, further comprising removing the heterogeneous layer.

In the aforementioned package substrate and method, a material forming the first circuit layer is different from a material forming the heterogeneous layer.

In the aforementioned package substrate and method, the heterogeneous layer is a conductive material excluding a copper layer. For example, the conductive material is an anisotropic conductive film.

As can be understood from the above, the package substrate and manufacturing method of the present disclosure can prevent the first circuit layer from being micro-etched when the heterogeneous layer is removed by the configuration of the heterogeneous layer. Therefore, when the heterogeneous layer is removed, a thickness of the first circuit layer can be effectively controlled. Compared with the prior art, the solder balls can be effectively bonded to the first circuit layer in the subsequent process of the present disclosure, thereby avoiding an issue of solder empty or non-wetting, so as to enhance a reliability of the package substrate.

Furthermore, through the configuration of the heterogeneous layer, part of the material of the first circuit layer would not be removed when the heterogeneous layer is removed, thereby lateral etching of the first circuit layer can be effectively prevented. Therefore, compared with the prior art, the present disclosure can avoid the problem of damage (such as break) of the first circuit layer, thereby enhancing the performance of signal transmission between the first circuit layer and the solder balls.

### BRIEF DESCRIPTION OF THE DRAWINGS

FIG. 1A to FIG. 1G are schematic diagrams of embodiments of the manufacturing method of the package substrate of the present disclosure.

FIG. 2A to FIG. 2G are schematic cross-sectional views of the manufacturing method of the package substrate of the present disclosure.

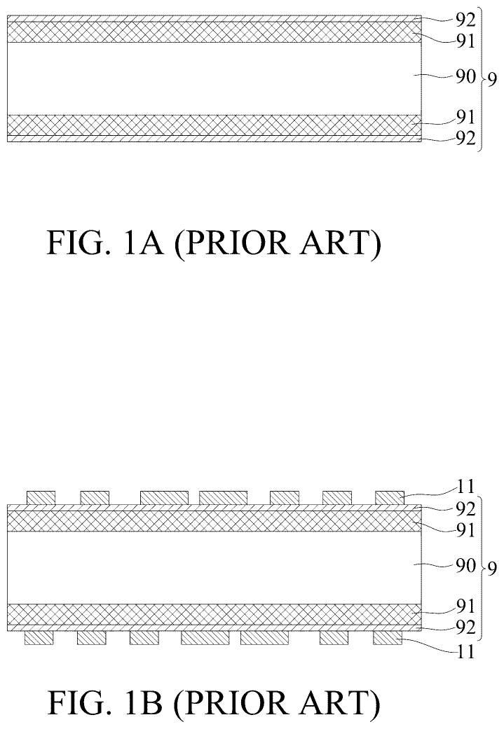

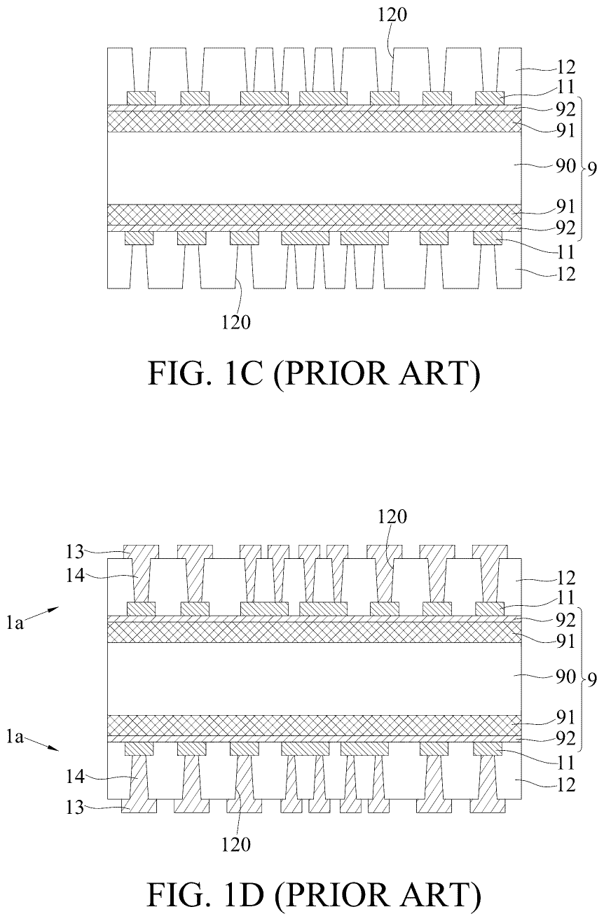

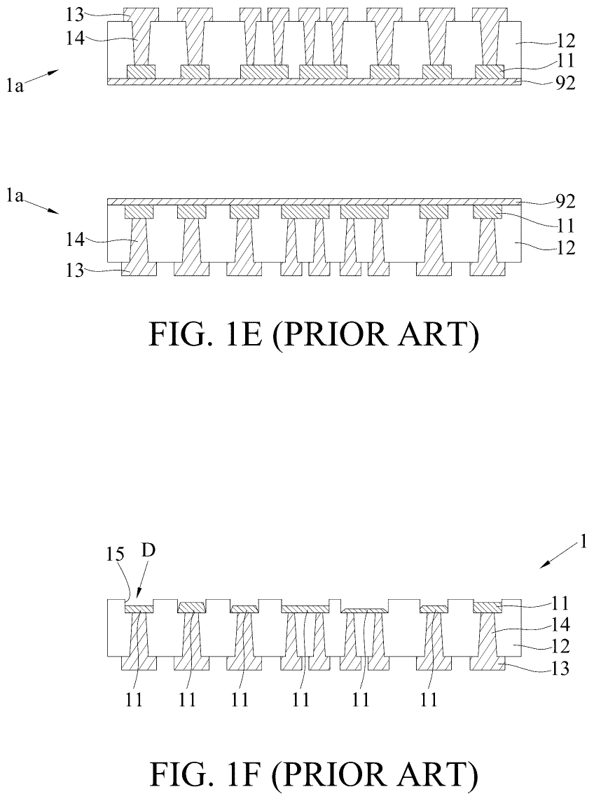

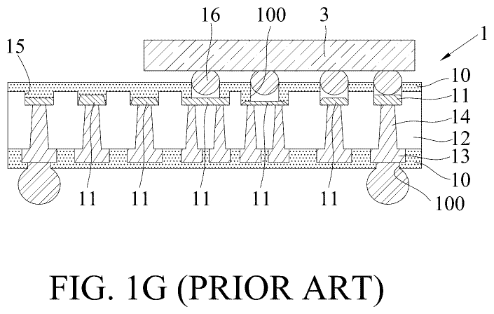

### DETAILED DESCRIPTION

Implementations of the present disclosure are described below by embodiments. Other advantages and technical effects of the present disclosure can be readily understood by one of ordinary skill in the art upon reading the disclosure of this specification.

It should be noted that the structures, ratios, sizes shown in the drawings appended to this specification are provided in conjunction with the disclosure of this specification in order to facilitate understanding by those skilled in the art. They are not meant, in any ways, to limit the implementations of the present disclosure, and therefore have no substantial technical meaning. Without influencing the effects created and objectives achieved by the present disclosure, any modifications, changes or adjustments to the structures, ratios, or sizes are construed as falling within the scope covered by the technical contents disclosed herein. Meanwhile, terms such as “on,” “first,” “second,” “a,” “one,” and the like, are for illustrative purposes, and are not meant to limit the scope implementable by the present disclosure. Any changes or adjustments made to the relative relationships, without substantially modifying the technical contents, are also to be construed as within the scope implementable by the present disclosure.

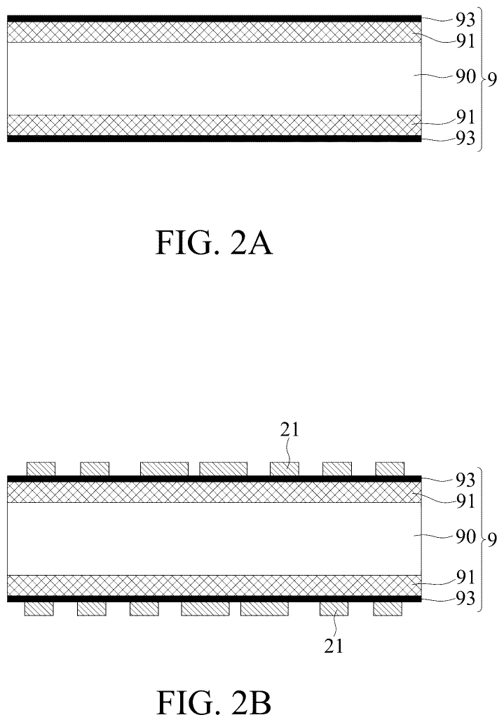

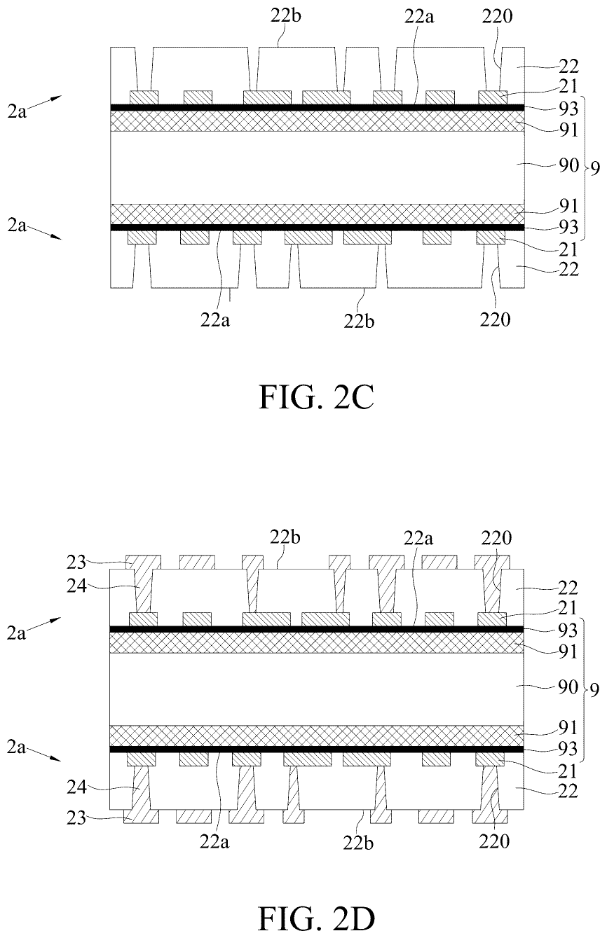

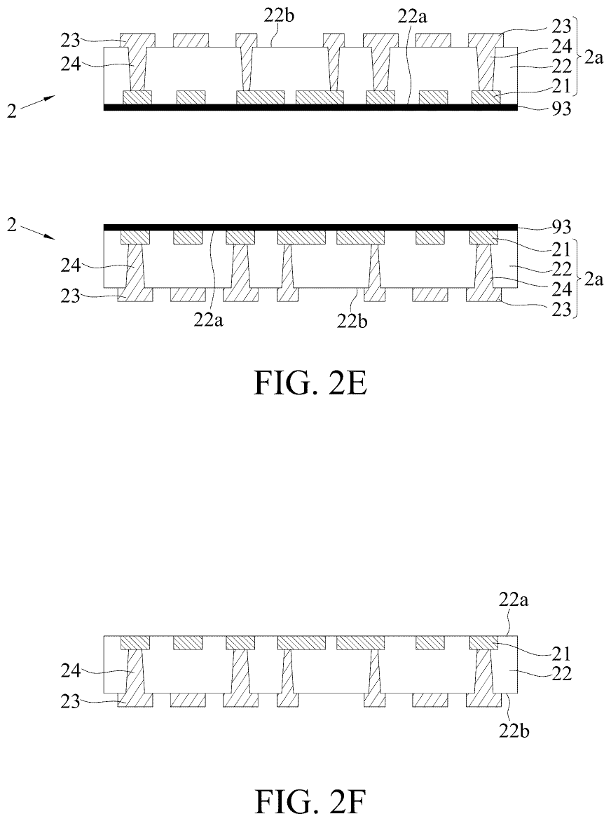

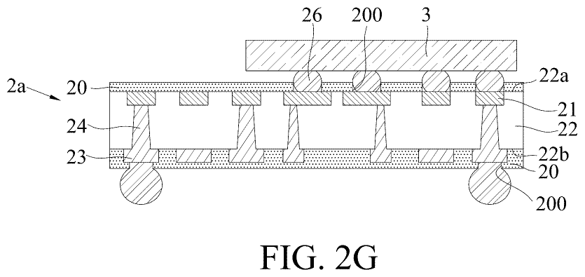

FIG. 2A to FIG. 2G are schematic cross-sectional views of the manufacturing method of the package substrate 2 of the present disclosure.

As shown in FIG. 2A, a carrier 9 is provided, of which a board body 90 is provided with release layers 91 on two opposite surfaces thereof, and a heterogeneous layer 93 is formed on each of the release layers 91.

In one embodiment, the heterogeneous layer 93 is a conductive material excluding a copper layer, such as anisotropic conductive film (ACF).

As shown in FIG. 2B, a patterned wiring process is performed to form a first circuit layer 21 on the heterogeneous layer 93.

In one embodiment, the first circuit layer 21 is made of copper, so that the material forming the first circuit layer 21 is different from a material forming the heterogeneous layer 93. For example, the first circuit layer 21 is a circuit redistribution layer (RDL) specification.

As shown in FIG. 2C, a dielectric layer 22 is formed on the heterogeneous layer 93 of the carrier 9 and is defined with a first surface 22a and a second surface 22b opposite to the first surface 22a. Therefore, the first surface 22a of the dielectric layer 22 is bonded to the heterogeneous layer 93, and a plurality of blind holes 220 are formed on the second surface 22b of the dielectric layer 22.

In one embodiment, the dielectric layer 22 is made of Ajinomoto build-up film (ABF), polybenzoxazole (PBO), or polyimide PI), prepreg (PP) including a glass fiber or other dielectric materials.

As shown in FIG. 2D, a second circuit layer 23 is formed on the second surface 22b of the dielectric layer 22, and a plurality of conductive blind holes 24 electrically connected to the first circuit layer 21 and the second circuit layer 21 are formed in the blind holes 220 of the dielectric layer 22 to form a coreless circuit structure 2a.

In one embodiment, the second circuit layer 23 is manufactured by electroplating the metal (such as copper) or other methods using a build-up process. For example, the plurality of blind holes 220 are first formed on the second surface 22b of the dielectric layer 22 by lasers, and then copper is electroplated on the dielectric layer 22 and in the blind holes 220, thereby the second circuit layer. 23 and the conductive blind hole 24 are integrally formed.

Furthermore, the second circuit layer 23 and the conductive blind holes 24 are copper materials. For example, the second circuit layer 23 and the conductive blind hole 24 are in a circuit redistribution layer (RDL) specification.

It should be understood that by using a build-up process, a number of layers of the dielectric layer 22 of the circuit structure 2a can be designed based on needs to manufacture the second circuit layers 23 with the required number of layers.

As shown in FIG. 2E, the board body 90 of the carrier 9 and the circuit structure 2a are separated by the release layer 91, and the heterogeneous layer 93 is remained on the first surface 22a of the dielectric layer 22.

In one embodiment, the release layer 91 is removed by lifting off or other methods.

As shown in FIG. 2F, the heterogeneous layer 93 is removed by etching, the first circuit layer 21 is embedded in the dielectric layer 22 and exposed from the first surface 22a of the dielectric layer 22, and the first circuit layer 21 is flush with the first surface 22a of the dielectric layer 22.

In one embodiment, an etchant etching the heterogeneous layer 93 (Ni material) includes a free hydrogen, nitrate, phosphate and/or metal ions, and therefore, when the heterogeneous layer 93 is etched, the first circuit layer 21 would not be etched.

As shown in FIG. 2G, an insulating protective layer 20 having a plurality of openings 200, such as a solder mask, is formed on the first surface 22a and the second surface 22b of the dielectric layer 22, respectively, and partial surfaces of the first circuit layer 21 and the second circuit layer 23 are exposed from the openings 200.

In addition, in subsequent processes, an electronic device 3 can be bonded to the first circuit layer 21 or the second circuit layer 23. In one embodiment, the electronic device 3 is attached and electrically connected to the first circuit layer 21 through a plurality of conductive elements 26. The electronic device 3 such as a semiconductor chip, a passive element, a silicon interposer, a circuit board or other elements forms an electronic package.

Therefore, the manufacturing method of the present disclosure can remove the heterogeneous layer 93 without slightly etching the first circuit layer 21 through forming the heterogeneous layer 93 that is formed by a material different from that of the first circuit layer 21. As such, the first circuit layer 21 is flush with the first surface 22a of the dielectric layer 22 after the heterogeneous layer 93 is removed, and no groove would be formed on the first surface 22a of the dielectric layer 22, such that the plurality of conductive elements 26 can be effectively bonded to the first circuit layer 21, thereby avoiding the problems of solder empty (i.e., the electronic device 3 is not soldered) or non-wetting.

Furthermore, since the material forming the first circuit layer 21 is different from the material forming the heterogeneous layer 93, part of the material of the first circuit layer 21 are not removed when the heterogeneous layer 93 is removed, so as to effectively avoid occurrence of lateral etching on the first circuit layer 21, thereby avoiding damage (such as break). Therefore, the problem of signal transmission between the first circuit layer 21 and the conductive element 26 can be avoided.

The present disclosure also provides a packaging substrate 2 including at least one dielectric layer 22, the first circuit layer 21, the heterogeneous layer 93, at least one second circuit layer 23 and the plurality of conductive blind holes 24.

The dielectric layer 22 has the first surface 22a and the second surface 22b opposite to the first surface 22a.

The first circuit layer 21 is embedded in the first surface 22a of the dielectric layer 22, and the first circuit layer 21 is flush with the first surface 22a of the dielectric layer 22.

The heterogeneous layer 93 is formed on the first surface 22a of the dielectric layer 22.

The second circuit layer 23 is formed on the second surface 22b of the dielectric layer 22.

The conductive blind hole 24 is formed in the dielectric layer 22 and electrically connected to the first circuit layer 21 and the second circuit layer 23.

In one embodiment, the first circuit layer 21 and the heterogeneous layer 93 are formed by different materials.

In one embodiment, the heterogeneous layer 93 is a conductive material except for a copper layer, such as an anisotropic conductive film.

In view of the above, in the package substrate and manufacturing method of the present disclosure, the first circuit layer can be effectively controlled to have a consistent thickness by the configuration of the heterogeneous layer, allowing the conductive element to be effectively bonded to the first circuit layer, avoiding the problem of solder empty or non-wetting, thereby enhancing the reliability.

Furthermore, part of the material of the first circuit layer would not be removed when the heterogeneous layer is removed, thereby lateral etching of the first circuit layer can be effectively prevented. Therefore, the present disclosure can avoid the problem of damage (such as break) of the first circuit layer, thereby enhancing the performance of signal transmission between the first circuit layer and the solder balls.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. A package substrate, comprising:
a dielectric layer having a first surface and a second surface opposite to the first surface;
a first circuit layer embedded in the first surface of the dielectric layer, wherein the first circuit layer is flush with the first surface of the dielectric layer;
a heterogeneous layer formed on the first surface of the dielectric layer;
a second circuit layer formed on the second surface of the dielectric layer; and
a plurality of conductive blind holes formed in the dielectric layer and electrically connected to the first circuit layer and the second circuit layer.

2. The package substrate of claim 1, wherein a material forming the first circuit layer is different from a material forming the heterogeneous layer.

3. The package substrate of claim 1, wherein the heterogeneous layer is a conductive material excluding a copper layer.

4. The package substrate of claim 3, wherein the conductive material is an anisotropic conductive film.

5. A method of manufacturing an electronic package, comprising:
providing a board body having a heterogeneous layer thereon;
forming a first circuit layer on the heterogeneous layer;
forming a dielectric layer on the heterogeneous layer and the first circuit layer, wherein the dielectric layer has a first surface and a second surface opposite to the first surface, and the first surface of the dielectric layer is bonded to the heterogeneous layer;
forming a second circuit layer on the second surface of the dielectric layer, and forming a plurality of conductive blind holes in the dielectric layer which are electrically connected to the first circuit layer and the second circuit layer in the dielectric layer; and
removing the board body.

6. The method of claim 5, wherein a material forming the first circuit layer is different from a material forming the heterogeneous layer.

7. The method of claim 5, wherein the heterogeneous layer is made from a conductive material exclusive of copper.

8. The method of claim 7, wherein the conductive material is an anisotropic conductive film.

9. The method of claim 5, wherein a release layer is first formed on the board body, and then the heterogeneous layer is formed on the release layer.

10. The method of claim 5, further comprising removing the heterogeneous layer.
